(19) United States
(12) Patent Application Publication
(10) Pub. No.: US 2013/0244054 A1
(43) Pub. Date: Sep. 19, 2013

(54) COMPOSITE MATERIAL AND METHOD FOR IMPROVING FATIGUE PROPERTIES OF TITANIUM ALLOY BY COATING METALLIC GLASS LAYER

(71) Applicants: Jinn P. Chu, Taipei City (TW); Cheng-Min Lee, Taipei City (TW); Shian-Ching Jang, Taoyuan County (TW)

(72) Inventors: Jinn P. Chu, Taipei City (TW); Cheng-Min Lee, Taipei City (TW); Shian-Ching Jang, Taoyuan County (TW)

(73) Assignee: National Taiwan University of Science and Technology, Taipei (TW)

(21) Appl. No.: 13/544,998

(22) Filed: Jul. 10, 2012

(30) Foreign Application Priority Data
Mar. 13, 2012 (TW) 101108493

(51) Int. Cl. B32B 15/04; C23C 14/35

(52) U.S. Cl. 428/631; 428/336; 204/192.15

(57) ABSTRACT

The invention provides a composite material, which includes a titanium alloy substrate and a metallic glass layer. The metallic glass layer is disposed on the titanium alloy substrate. The thickness of the metallic glass layer is 50 nm-200 nm, in which in comparison with the titanium alloy substrate, the fatigue life of the composite material of the invention is increased by 5-17 times.

### CROSS-REFERENCE TO RELATED APPLICATION

This application claims the priority benefit of Taiwan application serial no. 101108493, filed on Mar. 13, 2012. The entirety of the above-mentioned patent application is hereby incorporated by reference herein and made a part of this specification.

### BACKGROUND OF THE INVENTION

1. Field of the Invention

The invention generally relates to a composite material, and more particularly, to a composite material formed by a titanium alloy substrate with a metallic glass layer.

2. Description of Related Art

The titanium alloy substrate has lightweight, high ductility and high corrosion-resistant property and has broad applications in industry. To further enhance the applicability of the titanium alloy substrate, it needs to enhance the fatigue strength and lengthen the fatigue life of the titanium alloy substrate, in which as one of the improvement methods, it is a surface modification through coating and so on.

For the titanium alloy substrates such as a titanium alloy, in order to improve the fatigue strength and fatigue life, the commonly used method is to coat a layer of TiN, TiNₓ, or ZrN on the surface thereof and the film serves as a protective layer to enhance the fatigue properties of the titanium alloy substrate. TiN or ZrN belongs to a ceramic coating, so that in the manufacturing process, it requires a higher process temperature. Studies have shown that when conducting surface modification on the titanium alloy by using TiN or ZrN, the thermal effect under the high temperature process, on the contrary, decreases the titanium alloy's fatigue strength and fatigue life. The reason to cause such phenomena lies in the phase change with the titanium alloy at high temperatures. In addition, TiN or ZrN is hard and brittle, and thus the ductility thereof is insufficient, which can not effectively prevent the defects inside the material from spreading and growing during the fatigue test.

Therefore, in order to improve the application of the titanium alloy substrate, it is needed to develop a ductile material with high fatigue strength and low process temperature so as to conduct surface modification on the titanium alloy substrate.

### SUMMARY OF THE INVENTION

Accordingly, the invention is directed to a composite material aiming at solving the problem of the insufficient fatigue strength and fatigue life with a titanium alloy substrate so as to increase the application thereof.

The invention provides a composite material, which includes a titanium alloy substrate and a metallic glass layer. The thickness of the metallic glass layer is 50 nm-200 nm, in which in comparison with the above-mentioned titanium alloy substrate, the fatigue life of the composite material of the invention is increased by 5-17 times.

In an embodiment of the present invention, the above-mentioned metallic glass layer is disposed on the above-mentioned titanium alloy substrate by using a sputtering method below phase transition temperature.

In an embodiment of the present invention, the above-mentioned metallic glass layer is a metallic glass selected from a group consisting of Zr-based metallic glass, Mg-based metallic glass, La-based metallic glass, Pd-based metallic glass and Cu-based metallic glass.

In an embodiment of the present invention, the above-mentioned composite material further includes an adhesive layer disposed between the titanium alloy substrate and the metallic glass layer.

In an embodiment of the present invention, the above-mentioned adhesive layer is made of Ti metal or Cr metal.

Based on the description above, the composite material of the invention uses the metallic glass layer to improve the fatigue strength and fatigue life of the titanium alloy substrate, so that in comparison with the titanium alloy substrate without forming the metallic glass layer, the composite material of the invention has better mechanical property and application value.

The invention provides a method for fabricating a composite material, which includes: providing a titanium alloy substrate; and disposing a metallic glass layer on the titanium alloy substrate by using a low-temperature sputtering method, in which the process temperature of the low-temperature sputtering method is lower than 200° C.

In an embodiment of the present invention, the above-mentioned low-temperature sputtering method is magnetron sputtering method.

In an embodiment of the present invention, the thickness of the above-mentioned metallic glass layer is 50 nm-200 nm.

In an embodiment of the present invention, the above-mentioned metallic glass layer is a metallic glass selected from a group consisting of Zr-based metallic glass, Mg-based metallic glass, La-based metallic glass, Pd-based metallic glass and Cu-based metallic glass.

In an embodiment of the present invention, the above-mentioned composite material further includes an adhesive layer disposed between the titanium alloy substrate and the metallic glass layer.

In an embodiment of the present invention, the above-mentioned adhesive layer is made of Ti metal or Cr metal.

The invention provides a method for advancing the fatigue property of titanium alloy, which includes using a low-temperature sputtering method to form a metallic glass layer on a titanium alloy substrate, in which the above-mentioned metallic glass layer increases the fatigue life of the above-mentioned titanium alloy substrate by 5-17 times.

In an embodiment of the present invention, the above-mentioned metallic glass layer is a metallic glass selected from a group consisting of Zr-based metallic glass, Mg-based metallic glass, La-based metallic glass, Pd-based metallic glass and Cu-based metallic glass.

In an embodiment of the present invention, prior to forming the above-mentioned metallic glass layer, the method further includes forming an adhesive layer on the titanium alloy substrate.

In an embodiment of the present invention, the above-mentioned adhesive layer is made of Ti metal or Cr metal.

In an embodiment of the present invention, the above-mentioned metallic glass layer makes the fatigue life of the titanium alloy reach at least a number of cycles of 2.2×10⁶ under a stress of 1.3 GPa.

Based on the description above, in order to enhance the fatigue property of titanium alloy, the invention uses a magnetron sputtering method to sputter a metallic glass layer on the titanium alloy material. Due to lower process temperature, the thermal effects will not impact on the titanium alloy material and the titanium alloys still retain the original strength. By using the high strength and ductility of metallic glass, the fatigue strength and fatigue life of the titanium alloy substrate are increased. As a result, in comparison with the titanium alloy substrate without forming the metallic glass layer, the composite material of the invention has better mechanical properties and application value as well.

Other objectives, features and advantages of the present invention will be further understood from the further technological features disclosed by the embodiments of the present invention in which there are shown and described preferred embodiments of this invention, simply by way of illustration of modes best suited to carry out the invention.

### BRIEF DESCRIPTION OF THE DRAWINGS

FIG. 1 is a schematic cross-sectional diagram of a composite material according to an embodiment of the invention.

FIG. 2 is a schematic diagram showing a fatigue test.

FIG. 3(a) is a S—N four-point bending fatigue curve plot of a MG/Ti/Ti-6Al-4V specimen and a Ti-6Al-4V specimen. FIG. 3(b) is a S—N four-point bending fatigue curve plot of a MG/Ti/nickel alloy specimen and a Ti-6Al-4V specimen.

FIGS. 4(a) and 4(b) are surface roughness diagrams respectively corresponding to the Ti-6Al-4V specimen and the MG/Ti/Ti-6Al-4V specimen.

FIGS. 5(a)-5(d) are surface morphology diagrams of MG/Ti/Ti-6Al-4V specimens after a fatigue test under a stress of 1.3 GPa observed by an SEM.

### DESCRIPTION OF THE EMBODIMENTS

The invention uses the metallic glass film with good formability, mechanical property, physical property and chemical property in the surface modification study of a titanium alloy substrate so as to improve the fatigue strength and fatigue life of the titanium alloy substrate.

The metallic glass layer refers to a metallic glass, which is mainly based on non-crystalline structure and may contain a small amount of partial crystal structure or totally contain non-crystalline structure.

The metallic glass layer of the invention can be, for example, Zr-based metallic glass, and the Zr-based metallic glass can be a metallic glass containing, for example, Zr and at least two elements selected from a group consisting of Cu, Al, Ni, Ti, Be, Nd, Y, P, Si, Mg, Pd and La. The proportion of Zr in the total composition is between 40 at. % (atomic percentage) to 60 at. %. The general composition formula of the metallic glass layer in the invention can be, for example, ZrM_{y1} in which M_{y1} represents at least two elements selected from a group consisting of Cu, Al, Ni, Ti, Be, Nd, Y, P, Si, Mg, Pd and La. The metallic glass layer in the invention can be, for example, Zr₅₀Cu₂₇Al₁₆Ni₇, Zr₅₃Cu₂₉Al₁₂Ni₆, Zr₆₆Al₈Cu₇Ni₁₉, Zr₆₆Al₈Cu₁₂Ni₁₄, Zr₅₇Ti₅Al₁₀Cu₂₀Ni₈ or Zr₄₄Ti₁₁Cu₁₀Ni₁₀Be₂₅.

The metallic glass layer of the invention can be, for example, Mg-based metallic glass, and the Mg-based metallic glass can be a metallic glass containing, for example, Mg and at least two elements selected from a group consisting of Cu, Al, Ni, Ti, Be, Nd, Y, P, Si, Zr, Pd and La. The proportion of Mg in the total composition is between 60 at. % to 85 at. %. The general composition formula of the metallic glass layer in the invention can be, for example, MgM_{y2} in which M_{y2} represents at least two elements selected from a group consisting of Cu, Al, Ni, Ti, Be, Nd, Y, P, Si, Zr, Pd and La. The metallic glass layer in the invention can be, for example, Mg₈₀Ni₁₀Nd₁₀, Mg₇₀Ni₁₅Nd₁₅ or Mg₆₅Cu₂₅Y₁₀.

The metallic glass layer of the invention can be, for example, La-based metallic glass, and the La-based metallic glass can be a metallic glass containing, for example, La and at least two elements selected from a group consisting of Cu, Al, Ni, Ti, Be, Nd, Y, P, Si, Zr, Pd and Mg. The proportion of La in the total composition is between 50 at. % to 60 at. %. The general composition formula of the metallic glass layer in the invention can be, for example, LaM_{y3} in which M_{y3} represents at least two elements selected from a group consisting of Cu, Al, Ni, Ti, Be, Nd, Y, P, Si, Zr, Pd and Mg. The metallic glass layer in the invention can be, for example, La₅₅Al₂₅Ni₁₅Cu₅, La₅₅Al₂₅Ni₁₀Cu₁₀ or La₅₅Al₂₅Ni₅Cu₁₅.

The metallic glass layer of the invention can be, for example, Pd-based metallic glass, and the Pd-based metallic glass can be a metallic glass containing, for example, Pd and at least two elements selected from a group consisting of Cu, Al, Ni, Ti, Be, Nd, Y, P, Si, Zr, La and Mg. The proportion of Pd in the total composition is between 40 at. % to 80 at. %. The general composition formula of the metallic glass layer in the invention can be, for example, PdM_{y4} in which M_{y4} represents at least two elements selected from a group consisting of Cu, Al, Ni, Ti, Be, Nd, Y, P, Si, Zr, La and Mg The metallic glass layer in the invention can be, for example, Pd₄₀Cu₃₀Ni₁₀P₂₀, Pd₇₇Cu₆Si₁₇ or Pd₄₀Ni₄₀P₂₀.

The metallic glass layer of the invention can be, for example, Cu-based metallic glass, and the Cu-based metallic glass can be a metallic glass containing, for example, Cu and at least two elements selected from a group consisting of Al, Ni, Ti, Be, Nd, Y, P, Si, Zr, La, Pd and Mg. The proportion of Cu in the total composition is between 50 at. % to 65 at. %. The general composition formula of the metallic glass layer in the invention can be, for example, CuM_{y5} in which M_{y5} represents at least two elements selected from a group consisting of Al, Ni, Ti, Be, Nd, Y, P, Si, Zr, La, Pd and Mg. The metallic glass layer in the invention can be, for example, Cu₆₀Zr₃₀Ti₁₀ or Cu₅₄Zr₂₇Ti₉Be₁₀.

The composition of the metallic glass layer in the invention is not limited to the above-mentioned exemplary embodiments. In other embodiments, the composition of the metallic glass layer in the invention can contain any element suitable for forming the metallic glass. In the above-mentioned exemplary embodiments, the composition proportions of the metallic glass layer are mainly decided according to the formability of the glass. In fact, any metallic glass containing the above-mentioned elements and having good formability of the metallic glass can be used to form the metallic glass layer of the composite material of the invention.

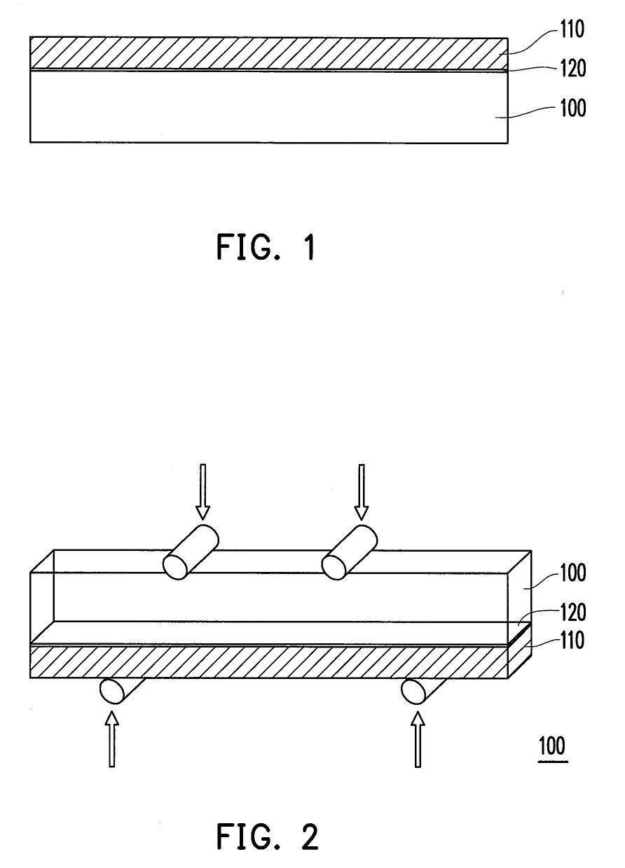

FIG. 1 is a schematic cross-sectional diagram of a composite material according to an embodiment of the invention. In association with FIG. 1, the composite material of the invention is explained.

Referring to FIG. 1, a composite material of the invention includes a titanium alloy substrate 100 and a metallic glass layer 110. The metallic glass layer 110 is disposed on the titanium alloy substrate 100. In an embodiment, a composite material of the invention further includes an adhesive layer 120 and the adhesive layer 120 is disposed between the titanium alloy substrate 100 and the metallic glass layer 110.

The material of the titanium alloy substrate 100 is not limited and it can use, for example, a commercially-available titanium alloy.

The metallic glass layer 110 is disposed on the titanium alloy substrate by using low-temperature sputtering method, which is, for example, a vacuum magnetron sputtering method. The vacuum magnetron sputtering method belongs to a low-temperature process with a process temperature lower than 200° C. During the process of sputtering the metallic glass layer, since the process temperature is relatively lower, so that the process has a lower thermal effect on the titanium alloy substrate and it can avoid negative influence of lowering the mechanical property by the thermal effect. The thickness of the metallic glass layer 110 is, for example, 50 nm-200 nm.

The material of the adhesive layer 120 can be, for example, titanium metal or chrome metal. The thickness of the adhesive layer 120 is, for example, 10 nm.

In the invention, the metallic glass layer is disposed on the titanium alloy substrate, so that in comparison with the conventional titanium alloy substrate without forming the metallic glass layer, the composite material of the invention has higher fatigue property such as higher fatigue strength and longer fatigue life. Such positive results are mainly caused by three factors. First, the metallic glass layer has excellent ductility and higher hardness. For the titanium alloy substrate, the metallic glass layer serves as a hard-film protection layer so as to prevent the spreading of the defects inside the titanium alloy substrate on the surface thereof. Next, the metallic glass layer can reduce the surface roughness of the titanium alloy substrate so as to reduce the probability for defects to develop nucleation and growing on the surface of the titanium alloy substrate. Further, the adhesion between the metallic glass layer and the titanium alloy substrate is high so as to prevent the spreading of the defects inside the titanium alloy substrate on the surface thereof.

The function of the adhesive layer lies in further enhancing the adhesive strength between the metallic glass layer and the titanium alloy substrate, however, the adhesive layer itself has no noticeable effect on the fatigue property of the titanium alloy.

In the conventional study on non-ferrous material, a scheme was provided that a metallic glass film is disposed on a Ni-based alloy by using sputtering process, where due to a poor adhesive strength between the film and the substrate material, the metallic glass film is easily peeled off from the substrate material. As a result, in the above-mentioned conventional scheme, the metallic glass film has a limited effect to improve the fatigue property of the Ni-based alloy where the fatigue life is improved by 3.9 times only. In comparison with the regular titanium alloy, the composite material of the invention has significant effect, in which the fatigue life is improved by 5-17 times. In addition, for the composite material of the invention, the fatigue life under a stress of 1.35 GPa can reach at least a number of cycles of 2.2×10⁶, which indicates in the composite material of the invention, the metallic glass film plays an important role to effectively improve the fatigue property of the titanium alloy.

Several experiment results on the composite material of the invention are described in following

### Experiment Example [Preparing MG/Ti/Ti-6Al-4V Specimen]

A vacuum magnetron sputtering method is used to deposit a titanium metal with a thickness of 10 nm (adhesive layer) on a Ti-6Al-4V substrate material (titanium alloy), followed by conducting the vacuum magnetron sputtering method again to deposit a Zr₅₀Cu₂₇Al₁₆Ni₇ metallic glass layer with a thickness of 200 nm to form a MG/Ti/Ti-6Al-4V specimen, in which the specimen dimension is 3×3×25 mm³.

The above-mentioned Ti-6Al-4V substrate material contains 5.5%-6.75% Al, 3.5%-4.5% V, 0.1% C (maximum content), 0.4% Fe (maximum content), 0.05% N, 0.02% O (maximum content), 0.015% H (maximum content), 0.4% of the remaining impurities (maximum content) and Ti (the balance of 100% by deducting the above-mentioned total content).

The process parameter of the above-mentioned magnetron sputtering method is: operation pressure is 10 mTorr, the working gas is argon gas, the flow is 20 sccm, the working distance is 100 mm (space between the target and the substrate), the time for coating 200 nm thickness of the zirconium-based metallic glass film is 1005 sec and the time for coating 10 nm thickness of the Ti adhesive layer is 65 sec.

### Reference Example 1

A Ti-6Al-4V specimen without sputtering is chosen as the reference example 1 for comparison, in which the Ti-6Al-4V specimen dimension is also 3×3×25 mm³.

### Reference Example 2

Except changing the above-mentioned Ti-6Al-4V material to nickel alloy material, the others are the same as the experiment example to prepare the MG/Ti/nickel alloy specimen.

A fatigue test is conducted on each of the specimens in the above-mentioned experiment example and reference examples 1 and 2, followed by measuring the surface roughness and observing the cross-section morphology of each specimen after the fatigue test by using a scanning electron microscopy (SEM).

FIG. 2 is a schematic diagram showing a fatigue test. Referring to FIG. 2, the fatigue test is a four-point bending test, and the spaces between the force-applying pins on the tensile-stress surface and the compressive-stress surface are 20 mm and 10 mm respectively. Each specimen undergoes a fatigue test under different stresses, in which load ratio R (minimum load/maximum load) applied onto each specimen is 0.1 and the test frequency is 10 Hz. The hatched portion in FIG. 2 refers to Zr₅₀Cu₂₇Al₁₆Ni₇ (metallic glass layer), from which it can be seen that during the fatigue test, the metallic glass layer is in tensile-stress state all the time.

The surface roughness is measured by an atomic force microscopy (AFM). An AFM of Model D3100 produced by Bruker Co. is used to contacted scan the specimen surface with a scan range of 50 μm×50 μm. After the measurement, a three-dimensional surface topography for each specimen is drawn so as to calculate a surface roughness thereof.

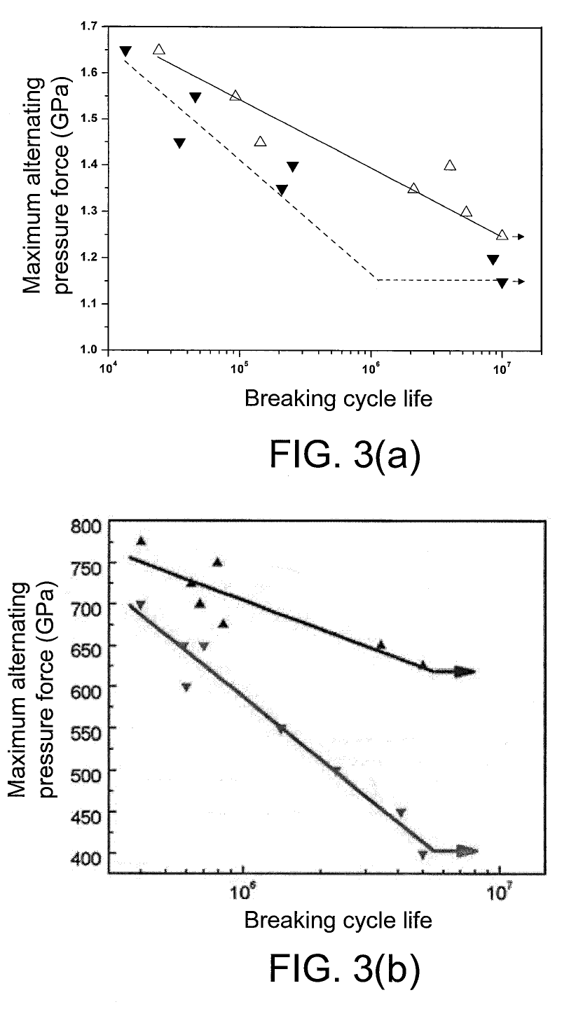

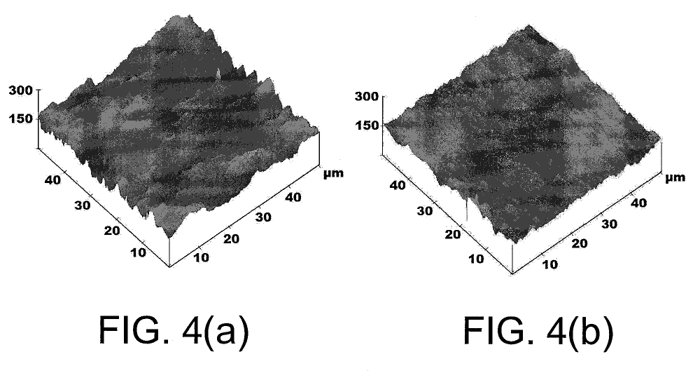

FIG. 3(a) is a S—N four-point bending fatigue curve plot of a MG/Ti/Ti-6Al-4V specimen and a Ti-6Al-4V specimen. FIG. 3(b) is a S—N four-point bending fatigue curve plot of a MG/Ti/nickel alloy specimen and a Ti-6Al-4V specimen, FIGS. 4(a) and 4(b) are surface roughness diagrams respectively corresponding to the Ti-6Al-4V specimen and the MG/Ti/Ti-6Al-4V specimen.

Referring to FIG. 3(a), in the plot, mark ‘Δ’ represents the S—N four-point bending fatigue curve of the MG/Ti/Ti-6Al-4V specimen and mark ‘▾’ represents the S—N four-point bending fatigue curve of the Ti-6Al-4V specimen. By comparing the MG/Ti/Ti-6Al-4V specimen with the Ti-6Al-4V specimen, it can be seen that under a larger load, the difference between the fatigue life of the MG/Ti/Ti-6Al-4V specimen and the fatigue life of the Ti-6Al-4V specimen is minor, i.e., the improve of the fatigue life is not noticeable. However, the improve extent of the fatigue life is increased along with decreasing the load. For example in FIG. 3(a), under a high-load stress of 1.65 GPa, the fatigue life of the MG/Ti/Ti-6Al-4V specimen is 2.4×10⁴ of number of cycles, while the fatigue life of the Ti-6Al-4V specimen is 1.3×10⁴ of number of cycles; under a low-load stress of 1.30 GPa, the fatigue life of the MG/Ti/Ti-6Al-4V specimen is 5.3×10⁶ of number of cycles, while the fatigue life of the Ti-6Al-4V specimen is 3.1×10⁵ of number of cycles. Moreover, regardless the type of the load, the fatigue life of the titanium alloy with sputtering a metallic glass layer, in comparison with the titanium alloy without the metallic glass layer, is increased, especially for the type under a low-load stress, the improvement of the fatigue life is more apparently. Additionally, in FIG. 3(a), it can be seen that the fatigue life of the titanium alloy with sputtering a metallic glass layer is increased by 5-17 times.

Referring to FIG. 3(b), in the plot, mark ‘▴’ represents the S—N four-point bending fatigue curve of the MG/Ti/nickel alloy specimen and in FIG. 3(a), mark ‘▾’ represents the S—N four-point bending fatigue curve of the Ti-6Al-4V specimen. By comparing FIG. 3(a) with FIG. 3(b), it can be seen that the effect of the metallic glass layer on the fatigue property of the nickel alloy is limited, where the fatigue life is improved by roughly 4 times only; but the metallic glass layer has significant effect on advancing the fatigue life of the titanium alloy, where the fatigue life is improved by roughly 5-17 times. In short, the metallic glass layer can be used to largely improve the fatigue property of the titanium alloy, where the fatigue property of the MG/Ti/Ti-6Al-4V specimen is better than the fatigue property of the MG/Ti/nickel alloy.

Referring to FIGS. 4(a) and 4(b), the surface roughness of the Ti-6Al-4V specimen is roughly 39.3 nm, and surface roughness of the MG/Ti/Ti-6Al-4V specimen is roughly 29.8 nm. In the test, the substrate material Ti-6Al-4V of the MG/Ti/Ti-6Al-4V specimen is the same as the substrate material of the Ti-6Al-4V specimen. Hence, the surface roughness of the Ti-6Al-4V specimen is measured first, then, a sputtering process is conducted on the Ti-6Al-4V specimen after the surface roughness measurement. The Zr₅₀Cu₂₇Al₁₆Ni₇ is sputtered on the titanium metal to form the MG/Ti/Ti-6Al-4V specimen. It can be seen from FIGS. 4(a) and 4(b), after sputtering the Zr₅₀Cu₂₇Al₁₆Ni₇ on the titanium metal, the surface roughness of the Ti-6Al-4V material is reduced, which further decreases the defects on the surface of the Ti-6Al-4V material.

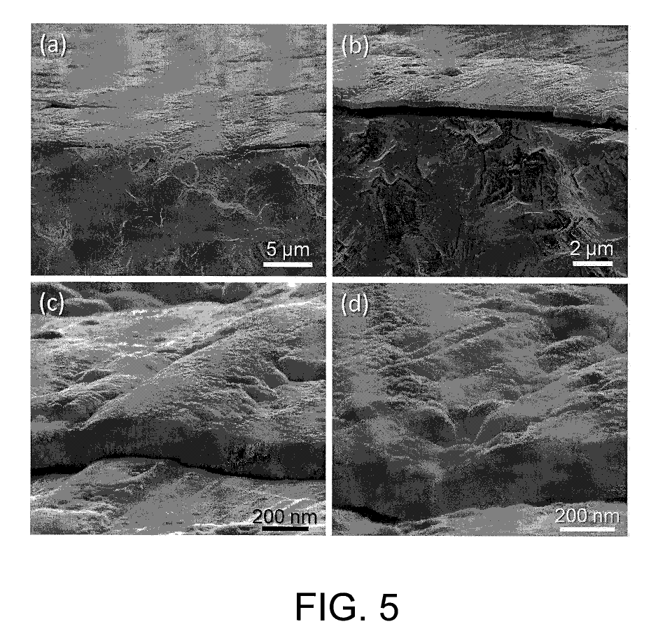

FIGS. 5(a)-5(d) are surface morphology diagrams of MG/Ti/Ti-6Al-4V specimens after a fatigue test under a stress of 1.3 GPa observed by an SEM. FIG. 5(a) indicates that after a fatigue fracture during the test under a stress of 1.3 GPa, except deformation and peeling phenomena occur at a breaking initiating region (shown by dotted-line area in FIG. 5(a)), Zr₅₀Cu₂₇Al₁₆Ni₇ can basically adhere onto the material surface and the surface keeps flat without noticeable deformation. The above-mentioned deformation and peeling phenomena are more noticeable in FIG. 5(b). In FIG. 5(c) indicates slip bands are stacked in the MG/Ti/Ti-6Al-4V specimen to generate defects on surface. The slip bands slip towards the surface to generate step-shaped offsets or, as shown by FIG. 5(d), to generate crack.

Continuing to FIGS. 5(c) and 5(d), it can be seen that Zr₅₀Cu₂₇Al₁₆Ni₇ overlays the above-mentioned offsets and cracks, which indicates Zr₅₀Cu₂₇Al₁₆Ni₇ has quite good ductility and strength. In particular, Zr₅₀Cu₂₇Al₁₆Ni₇ overlays the area with larger deformations such as offsets, so that multi-granular protrusions are generated on the Zr₅₀Cu₂₇Al₁₆Ni₇ surface. In comparison with other non-deformation areas, the Zr₅₀Cu₂₇Al₁₆Ni₇ surface still keeps flat. As a result, the metallic glass layer during the fatigue test can prevent generating defects or cracks on the material surface and thereby the fatigue life of the material is lengthened.

In summary, the composite material of the invention uses a metallic glass layer for increasing the fatigue strength and the fatigue life of the titanium alloy substrate. In comparison with the titanium alloy substrate without forming the metallic glass layer, the above-mentioned composite material of the invention has better mechanical property and application value.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. A composite material, comprising:
a titanium alloy substrate; and
a metallic glass layer, disposed on the titanium alloy substrate, wherein the thickness of the metallic glass layer is 50 nm-200 nm;
wherein the metallic glass layer makes the fatigue life of the composite material reach at least a number of cycles of 2.2×10⁶ under a stress of 1.3 GPa.

2. The composite material as claimed in claim 1, wherein the metallic glass layer is disposed on the titanium alloy substrate by using a low-temperature sputtering method.

3. The composite material as claimed in claim 1, wherein the metallic glass layer is a metallic glass selected from a group consisting of Zr-based metallic glass, Mg-based metallic glass, La-based metallic glass, Pd-based metallic glass and Cu-based metallic glass.

4. The composite material as claimed in claim 1, further comprising an adhesive layer disposed between the titanium alloy substrate and the metallic glass layer, wherein the adhesive layer is made of Ti metal or Cr metal.

5. A method for fabricating a composite material, comprising:
providing a titanium alloy substrate; and
disposing a metallic glass layer on the titanium alloy substrate by using a low-temperature sputtering method, wherein
the process temperature of the low-temperature sputtering method is lower than 200° C.

6. The method for fabricating a composite material as claimed in claim 5, wherein the low-temperature sputtering method is magnetron sputtering method.

7. The method for fabricating a composite material as claimed in claim 5, wherein the thickness of the metallic glass layer is 50 nm-200 nm.

8. The method for fabricating a composite material as claimed in claim 5, wherein the metallic glass layer is a metallic glass selected from a group consisting of Zr-based metallic glass, Mg-based metallic glass, La-based metallic glass, Pd-based metallic glass and Cu-based metallic glass.

9. The method for fabricating a composite material as claimed in claim 5, further comprising an adhesive layer disposed between the titanium alloy substrate and the metallic glass layer, wherein the adhesive layer is made of Ti metal or Cr metal.

10. The method for advancing the fatigue property of titanium alloy as claimed in claim 5, wherein the metallic glass layer makes the fatigue life of the titanium alloy reach at least a number of cycles of 2.2×10⁶ under a stresses of 1.3 GPa.
